(19) United States
(12) Patent Application Publication
(10) Pub. No.: US 2023/0337451 A1
(43) Pub. Date: Oct. 19, 2023

(54) ORGANIC ELECTROLUMINESCENT DEVICE AND FULL-COLOR DISPLAY INCLUDING THE SAME

(71) Applicant: BEIJING SUMMER SPROUT TECHNOLOGY CO., LTD., Beijing (CN)

(72) Inventors: Jing WANG, Beijing (CN); Huiqing PANG, Beijing (CN); Qi LIU, Beijing (CN); Chuanjun XIA, Beijing (CN)

(21) Appl. No.: 18/133,432

(22) Filed: Apr. 11, 2023

(30) Foreign Application Priority Data
Apr. 15, 2022 (CN) 202210394466.9

(51) Int. Cl. H10K 50/12; H10K 50/818; H10K 50/828

(52) U.S. Cl. CPC H10K 50/12; H10K 50/818; H10K 50/828; H10K 2102/351

(57) ABSTRACT

Provided are an organic electroluminescent device and a full-color display thereof. The organic electroluminescent device is a top-emitting device. Since an organic luminescent dopant material having a narrow full width at half maximum and a specific maximum emission wavelength is included in the organic layer, when the maximum current efficiency is reached, the color coordinates corresponding to the organic electroluminescent device satisfy: 0.165≤CIEx≤0.175, and 0.770≤CIEy≤0.800. The organic electroluminescent device enables a full-color display that includes the device to have a higher coverage of BT.2020. Further provided is a full-color display.

### CROSS-REFERENCE TO RELATED APPLICATION(S)

This application claims priority to Chinese Patent Application No. 202210394466.9 filed Apr. 15, 2022, the disclosure of which is incorporated herein by reference in its entirety.

### TECHNICAL FIELD

The present disclosure relates to organic electronic devices, for example, organic luminescent devices. More particularly, the present disclosure relates to a top-emitting organic electroluminescent device that includes an organic luminescent dopant material having a narrow full width at half maximum and a specific maximum emission wavelength.

### BACKGROUND

Organic electronic devices include, but are not limited to, the following types: organic light-emitting diodes (OLEDs), organic field-effect transistors (O-FETs), organic light-emitting transistors (OLETs), organic photovoltaic devices (OPVs), dye-sensitized solar cells (DSSCs), organic optical detectors, organic photoreceptors, organic field-quench devices (OFQDs), light-emitting electrochemical cells (LECs), organic laser diodes and organic plasmon emitting devices.

In 1987, Tang and VanSlyke of Eastman Kodak reported a bilayer organic electroluminescent device, which comprises an arylamine hole transporting layer and a tris-8-hydroxyquinolato-aluminum layer as the electron and emitting layer (Applied Physics Letters, 1987, 51 (12): 913-915). Once a bias is applied to the device, green light was emitted from the device. This device laid the foundation for the development of modern organic light-emitting diodes (OLEDs). State-of-the-art OLEDs may comprise multiple layers such as charge injection and transporting layers, charge and exciton blocking layers, and one or multiple emissive layers between the cathode and anode. Since the OLED is a self-emitting solid state device, it offers tremendous potential for display and lighting applications. In addition, the inherent properties of organic materials, such as their flexibility, may make them well suited for particular applications such as fabrication on flexible substrates.

The OLED can be categorized as three different types according to its emitting mechanism. The OLED invented by Tang and VanSlyke is a fluorescent OLED. It only utilizes singlet emission. The triplets generated in the device are wasted through nonradiative decay channels. Therefore, the internal quantum efficiency (IQE) of the fluorescent OLED is only 25%. This limitation hindered the commercialization of OLED. In 1997, Forrest and Thompson reported phosphorescent OLED, which uses triplet emission from heavy metal containing complexes as the emitter. As a result, both singlet and triplets can be harvested, achieving 100% IQE. The discovery and development of phosphorescent OLED contributed directly to the commercialization of active-matrix OLED (AMOLED) due to its high efficiency. Recently, Adachi achieved high efficiency through thermally activated delayed fluorescence (TADF) of organic compounds. These emitters have small singlet-triplet gap that makes the transition from triplet back to singlet possible. In the TADF device, the triplet excitons can go through reverse intersystem crossing to generate singlet excitons, resulting in high IQE.

OLEDs can also be classified as small molecule and polymer OLEDs according to the forms of the materials used. A small molecule refers to any organic or organometallic material that is not a polymer. The molecular weight of the small molecule can be large as long as it has well defined structure. Dendrimers with well-defined structures are considered as small molecules. Polymer OLEDs include conjugated polymers and non-conjugated polymers with pendant emitting groups. Small molecule OLED can become the polymer OLED if post polymerization occurred during the fabrication process.

There are various methods for OLED fabrication. Small molecule OLEDs are generally fabricated by vacuum thermal evaporation. Polymer OLEDs are fabricated by solution process such as spin-coating, inkjet printing, and slit printing. If the material can be dissolved or dispersed in a solvent, the small molecule OLED can also be produced by solution process.

The emitting color of the OLED can be achieved by emitter structural design. An OLED may comprise one emitting layer or a plurality of emitting layers to achieve desired spectrum. In the case of green, yellow, and red OLEDs, phosphorescent emitters have successfully reached commercialization. Blue phosphorescent device still suffers from non-saturated blue color, short device lifetime, and high operating voltage. Commercial full-color OLED displays normally adopt a hybrid strategy, using fluorescent blue and phosphorescent yellow, or red and green. At present, efficiency roll-off of phosphorescent OLEDs at high brightness remains a problem. In addition, it is desirable to have more saturated emitting color, higher efficiency, and longer device lifetime.

The standard definition of color gamut is as follows: a method of encoding colors. Color gamut also refers to the sum of colors that a technical system can produce. With the advent of ultra-high resolution displays such as 4K and 8K, users have increased demand for such displays' color performance. In 2012, the International Telecommunication Union (ITU) announced a new UHDTV color gamut standard, namely, Broadcast Service Television 2020 (BT.2020). Although BT.2020 has a higher color gamut specification, the three primary colors of BT.2020 are too saturated, making it difficult for general devices to achieve.

The monochromatic laser light source can be adopted to meet requirements of BT.2020 color gamut, but can only be applied to projection-type television displays. Moreover, due to its relatively large physical size and high manufacturing costs, its application to high-resolution small and medium-sized active matrix displays is almost impossible. Another potential candidate for meeting BT.2020 color gamut requirement is Quantum Dots (QD), because QD is widely studied owing to its relatively narrow emission spectrum. However, a quantum dot light-emitting diode using QD as a self-emitting element still has a problem of stability and cannot be commercialized. Moreover, the Micro LED technology, which strips the LED chip prepared on the semiconductor epitaxial wafer, transfers it to the display backplane, and bonds it with the backplane circuit (bonding), becomes a research hotspot of the novel display technology. The Micro LED chip has the same characteristics of narrow spectrum and high color saturation as the LED. A desired emission spectrum can be obtained by selection of an appropriate semiconductor material. However, the efficiency of the Micro LED chip decreases when the size is reduced. The existing “mass transfer” technology is immature. As a result, application of the Micro LED chip as a display component of mobile devices such as mobile phones has not yet been commercialized.

Organic light-emitting diode (OLED) displays have been widely used in displays of various sizes, such as mobile phones, tablets, notebook computers, ARs, or VR glasses. Several studies have shown that the power consumption of OLEDs may be 37% lower than that of LED backlit liquid crystal displays. Therefore, another potential candidate for meeting BT.2020 color gamut requirement is OLED technology. However, it is difficult for existing OLED devices to achieve the ideal BT.2020 color gamut coverage. The BT.2020 coverage of OLED products of major screen manufacturers and terminal manufacturers is generally less than 80%. Therefore, how to improve the BT.2020 coverage of OLED devices or OLED display products is an urgent technical problem to be solved in the art.

### SUMMARY

The present disclosure provides a series of new organic electroluminescent devices to solve at least part of the preceding problems. The organic electroluminescent device is a top-emitting device. Since an organic luminescent dopant material having a narrow full width at half maximum and a specific maximum emission wavelength is included in the organic layer, when the maximum current efficiency is reached, the color coordinates of the organic electroluminescent device satisfy: 0.165≤CIEx≤0.175, and 0.770≤CIEy≤0.800. The organic electroluminescent device enables a full-color display that includes the device to have a higher coverage of BT.2020.

According to an embodiment of the present disclosure, an organic electroluminescent device is disclosed, the organic electroluminescent device at least includes a substrate, a first electrode disposed on the substrate, a second electrode disposed on the first electrode, and an organic layer disposed between the first electrode and the second electrode;
the first electrode has high reflectivity; the second electrode is translucent or transparent;
wherein, the organic layer further includes an organic luminescent dopant material, PL spectrum of the organic luminescent dopant material satisfies both FWHM≤32 nm and 523 nm≤λₘₐₓ≤533 nm;
color coordinates (CIEx, CIEy) of the organic electroluminescent device, when maximum current efficiency CEₘₐₓ is reached, satisfy the following conditions:

0.110≤CIEx≤0.230;

0.750≤CIEy≤0.820.

According to an embodiment of the present disclosure, the color coordinates satisfy:

0.150≤CIEx≤0.200.

According to an embodiment of the present disclosure, the color coordinates satisfy:

0.165≤CIEx≤0.175.

According to an embodiment of the present disclosure, the color coordinates satisfy:

0.750≤CIEy≤0.813.

According to an embodiment of the present disclosure, the color coordinates satisfy:

0.770≤CIEy≤0.800.

According to an embodiment of the present disclosure, the PL spectrum of the organic luminescent dopant material satisfies the following conditions:

28 nm<FWHM≤32 nm, and 523 nm≤λₘₐₓ≤527 nm.

According to an embodiment of the present disclosure, the PL spectrum of the organic luminescent dopant material satisfies the following conditions:

22 nm<FWHM≤28 nm, and 523 nm≤λₘₐₓ≤527 nm.

According to an embodiment of the present disclosure, the PL spectrum of the organic luminescent dopant material satisfies the following conditions:

16 nm<FWHM≤22 nm, and 525 nm≤λₘₐₓ≤529 nm.

According to an embodiment of the present disclosure, the PL spectrum of the organic luminescent dopant material satisfies the following conditions:

FWHM≤16 nm, and 529 nm≤λₘₐₓ≤533 nm.

According to an embodiment of the present disclosure, the CEₘₐₓ≥160 cd/A.

According to an embodiment of the present disclosure, the organic electroluminescent device has a device lifetime LT95≥30 h at an initial brightness condition of 110000 cd/m².

The device lifetime LT95 refers to the time it takes for the device brightness to decay to 95% of the initial brightness. In this embodiment, LT95 refers to the time it takes for the organic electroluminescent device brightness to decay to 95% of the initial 110000 cd/m².

According to an embodiment of the present disclosure, the organic electroluminescent device has a device lifetime that LT95≥30 h under the condition of a constant current density of 80 mA/cm².

The device lifetime LT95 refers to the time it takes for the device brightness to decay to 95% of the initial brightness. In this embodiment, LT95 refers to the time it takes for the organic electroluminescent device brightness to decay to 95% of the initial brightness under the condition of a constant current density of 80 mA/cm².

According to an embodiment of the present disclosure, the device lifetime LT95≥35 h.

According to an embodiment of the present disclosure, the device lifetime LT95≥40 h.

According to an embodiment of the present disclosure, the device lifetime LT95≥45 h.

According to an embodiment of the present disclosure, the organic electroluminescent device is a top-emitting device.

According to an embodiment of the present disclosure, the first electrode is an anode, and the second electrode is a cathode.

According to an embodiment of the present disclosure, the average reflectivity of the first electrode in the visible light region is greater than 70%.

According to an embodiment of the present disclosure, the average reflectivity of the first electrode in the visible light region is greater than 80%.

According to an embodiment of the present disclosure, the average reflectivity of the first electrode in the visible light region is greater than 85%.

According to an embodiment of the present disclosure, the average transmittance of the second electrode in the visible light region is greater than 15%.

According to an embodiment of the present disclosure, the average transmittance of the second electrode in the visible light region is greater than 20%.

According to an embodiment of the present disclosure, the average transmittance of the second electrode in the visible light region is greater than 25%.

According to an embodiment of the present disclosure, the first electrode is selected from a group consisting of Ag, Al, Ti, Cr, Pt, Ni, TiN, and from a combination of preceding materials with ITO and/or MoOx (molybdenum oxide);

the second electrode includes a material selected from a group consisting of MgAg alloy, MoOx, Yb, Ca, ITO, IZO, and from a combination of preceding materials.

According to another embodiment of the present disclosure, a full-color display is also disclosed, which includes an organic electroluminescent device. The specific structure of the organic electroluminescent device is as described in any of the preceding embodiments.

According to an embodiment of the present disclosure, wherein color coordinates of red light of the full-color display comprise (0.708, 0.292), and color coordinates of blue light of the full-color display comprise (0.131, 0.046).

According to an embodiment of the present disclosure, the BT.2020 coverage of the full-color display is greater than or equal to 85%.

According to an embodiment of the present disclosure, the BT.2020 coverage of the full-color display is greater than or equal to 90%.

According to an embodiment of the present disclosure, the BT.2020 coverage of the full-color display is greater than or equal to 95%.

A series of novel organic electroluminescent devices disclosed in the present disclosure are top-emitting devices. Since an organic luminescent dopant material having a narrow full width at half maximum and a specific maximum emission wavelength is included in the organic layer, when the maximum current efficiency is reached, the color coordinates of the organic electroluminescent device satisfy: 0.165≤CIEx≤0.175, and 0.770≤CIEy≤0.800. The organic electroluminescent device enables a full-color display that includes the device to have a higher coverage of BT.2020.

### BRIEF DESCRIPTION OF DRAWINGS

FIG. 1 is a diagram illustrating the structure of a typical top-emitting OLED device.

FIG. 2A is a diagram of the situation in which the color coordinate point P4 falls within the range of BT.2020 color coordinates.

FIG. 2B is a diagram of the situation in which the color coordinate point P4 falls outside the range of BT.2020 color coordinates.

FIG. 3A is a diagram illustrating the structure of a device structure used for simulation according to the present disclosure.

FIG. 3B is a PL spectrum used for simulating the designed organic electroluminescent device with FWHM of 28 nm according to the present disclosure.

FIG. 4 is a three-dimensional diagram of color coordinates and current efficiency under the condition of certain FWHM and λₘₐₓ.

FIG. 5A is a graph showing the relationship between CIEx and λₘₐₓ, where FWHM=16 nm.

FIG. 5B is a graph showing the relationship between CIEy and λₘₐₓ, where FWHM=16 nm.

FIG. 5C is a graph showing the relationship between CIEx and FWHM, where λₘₐₓ=525 nm.

FIG. 5D is a graph showing the relationship between CIEy and FWHM, where λₘₐₓ=525 nm.

FIG. 6 is a PL spectrum of compound GD according to an embodiment of the present disclosure.

### DETAILED DESCRIPTION

As used herein, “top” refers to the farthest from a substrate, and “bottom” means the closest to the substrate. Where a first layer is described as “disposed on” a second layer, the first layer is disposed further away from the substrate. On the contrary, where a first layer is described as “disposed below” a second layer, the first layer is disposed closer to the substrate. There may be other layers between the first and second layers, unless it is specified that the first layer is “in contact with” the second layer. For example, a cathode may be described as “disposed on” an anode, even though there are various organic layers between the cathode and the anode.

As used in the present disclosure, the term “encapsulation layer” may be a thin-film encapsulation with a thickness less than 100 micrometers, which includes disposing one or more thin films directly on the device or may be a cover glass gluing to the substrate.

Devices fabricated in accordance with embodiments of the present disclosure can be incorporated into a wide variety of consumer products that have one or more of the electronic component modules (or units) incorporated therein. Some examples of such consumer products include flat panel displays, monitors, medical monitors, televisions, billboards, lights for interior or exterior illumination and/or signaling, heads-up displays, fully or partially transparent displays, flexible displays, smart phones, tablets, phablets, wearable devices, smart watches, laptop computers, digital cameras, camcorders, viewfinders, micro-displays, 3-D displays, vehicles displays, and vehicle tail lights.

As used herein, “solution processible” means capable of being dissolved, dispersed, or transported in and/or deposited from a liquid medium, either in solution or suspension form.

A ligand may be referred to as “photoactive” when it is believed that the ligand directly contributes to the photoactive properties of an emissive material. A ligand may be referred to as “ancillary” when it is believed that the ligand does not contribute to the photoactive properties of an emissive material, although an ancillary ligand may alter the properties of a photoactive ligand.

It is believed that the internal quantum efficiency (IQE) of fluorescent OLEDs can exceed the 25% spin statistics limit through delayed fluorescence. As used herein, there are two types of delayed fluorescence, i.e. P-type delayed fluorescence and E-type delayed fluorescence. P-type delayed fluorescence is generated from triplet-triplet annihilation (TTA).

On the other hand, E-type delayed fluorescence does not rely on the collision of two triplets, but rather on the transition between the triplet states and the singlet excited states. Compounds that are capable of generating E-type delayed fluorescence are required to have very small singlet-triplet gaps to convert between energy states. Thermal energy can activate the transition from the triplet state back to the singlet state. This type of delayed fluorescence is also known as thermally activated delayed fluorescence (TADF). A distinctive feature of TADF is that the delayed component increases as temperature rises. If the reverse intersystem crossing (RISC) rate is fast enough to minimize the non-radiative decay from the triplet state, the fraction of back populated singlet excited states can potentially reach 75%. The total singlet fraction can be 100%, far exceeding 25% of the spin statistics limit for electrically generated excitons.

E-type delayed fluorescence characteristics can be found in an exciplex system or in a single compound. Without being bound by theory, it is believed that E-type delayed fluorescence requires the luminescent material to have a small singlet-triplet energy gap (AEs-T). Organic, non-metal containing, donor-acceptor luminescent materials may be able to achieve this. The emission in these materials is generally characterized as a donor-acceptor charge-transfer (CT) type emission. The spatial separation of the HOMO and LUMO in these donor-acceptor type compounds generally results in small ΔE_{S-T}. These states may involve CT states. Generally, donor-acceptor luminescent materials are constructed by connecting an electron donor moiety such as amino- or carbazole-derivatives and an electron acceptor moiety such as N-containing six-membered aromatic rings.

As used herein, the term “color coordinates” refers to the corresponding coordinates in the CIE 1931 color space.

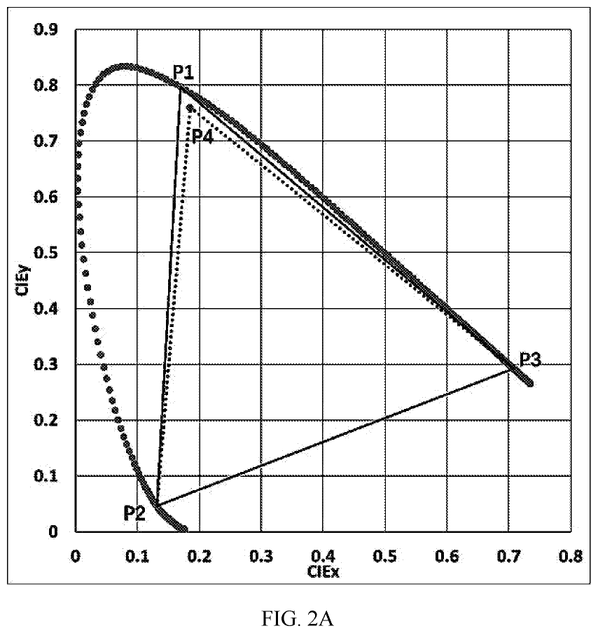

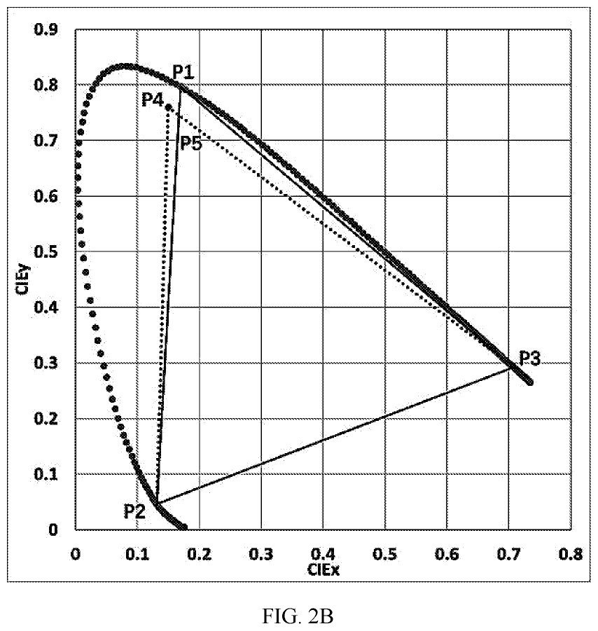

As used herein, the term “BT.2020 coverage” refers to the ratio of the area of the overlapping part of triangle a and triangle b to the area of triangle b in the CIE 1931 color space. In the CIE 1931 color space, the triangle a is surrounded by color coordinates of red light (0.708, 0.292), color coordinates of blue light (0.131, 0.046), and color coordinates of specific green light CIE (x, y). In the CIE 1931 color space, the triangle b (that is, the range of BT.2020 color coordinates) is surrounded by color coordinates of red light (0.708, 0.292), color coordinates of blue light (0.131, 0.046), and color coordinates of green light (0.170, 0.797). For example, as shown in FIG. 2A, a point whose color coordinates are (0.170, 0.797) is named P₁. A point whose color coordinates are (0.131, 0.046) is named P₂. A point whose color coordinates are (0.708, 0.292) is named P₃. The triangle P₁P₂P₃ is the triangle b. When a point P₄ of the specific green light color coordinates falls inside the triangle P₁P₂P₃, the BT.2020 coverage=(the area of triangle P₄P₂P₃)/(the area of triangle P₁P₂P₃). When the point P₄ of the specific green light color coordinates falls outside the triangle P₁P₂P₃, as shown in FIG. 2B, it is necessary to first determine the point P₅ where the straight line P₄P₃ intersects with a side of the triangle P₁P₂P₃ (such as the side P₁P₂), and BT.2020 coverage=(the area of triangle P₅P₂P₃)/(the area of triangle P₁P₂P₃).

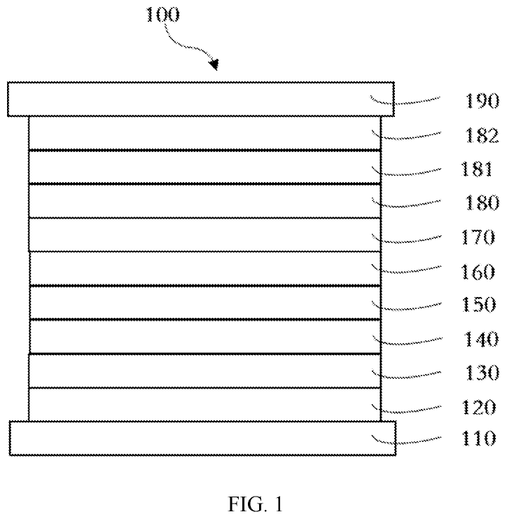

The structure of a typical top-emitting OLED device is shown in FIG. 1. An OLED device 100 includes an anode 110, a hole injection layer (HIL) 120, a hole transporting layer (HTL) 130, an electron blocking layer (EBL) 140 (also called a prime layer), an emissive layer (EML) 150, a hole blocking layer (HBL) 160 (hole blocking layer 160 is an optional layer), an electron transporting layer (ETL) 170, an electron injection layer (EIL) 180, a cathode 181, a capping layer 182, and an encapsulation layer 190. The anode 110 is a material or a combination of materials having high reflectivity, including but not limited to, Ag, Al, Ti, Cr, Pt, Ni, TiN, and a combination of preceding materials with ITO and/or MoOx (molybdenum oxide). Typically, the reflectivity of the anode is greater than 50%; preferably, the reflectivity of the anode is greater than 70%; more preferably, the reflectivity of the anode is greater than 80%. The cathode 181 should be a translucent or transparent conductive material, including but not limited to, MgAg alloys, MoOx, Yb, Ca, ITO, IZO, or a combination thereof. The average transmittance of light with a wavelength in a visible light region is greater than 15%; preferably, the average transmittance of light with a wavelength in the visible light region is greater than 20%; more preferably, the average transmittance of light with a wavelength in the visible light region is greater than 25%. The hole injection layer 120 may be a layer of single material such as commonly used HATCN. The hole injection layer 120 may also be formed with a hole transporting material doped with a certain proportion of p-type conductive dopant material, where the doping proportion is generally not higher than 5% and commonly between 1% and 3%. The EBL 140 is an optional layer. However, to better match the energy level of the host material, a device structure with EBL is generally adopted. The thickness of the hole transporting layer is generally between 100 nm to 200 nm. Since the top-emitting device has a micro-cavity effect, the micro-cavity of the device is generally adjusted by adjustment of the thickness of the hole transporting layer. For example, to optimize the micro-cavity effect of a top-emitting OLED device, that is, to achieve the highest current efficiency, it is common practice to fix the thickness of the EBL and then adjust the micro-cavity by adjustment of the thickness of the HTL. Those skilled in the art can obviously understand that two top-emitting devices, if only different in the material used for one organic layer in the device, for example, only EBLs adopt different organic materials (the other functional layers are the same), the optimal micro-cavity lengths of the two top-emitting devices may have slight differences since the refractive index of the different organic materials in the EBL may be slightly different.

As used herein, “average transmittance in a visible light region” refers to the sum of transmittances in the wavelength range of 380 nm to 780 nm divided by the number of test points. For example, if one point is taken for every 1 nm, then the number of test points is 401; if one point is taken every 2 nm, then the number of test points is 200.

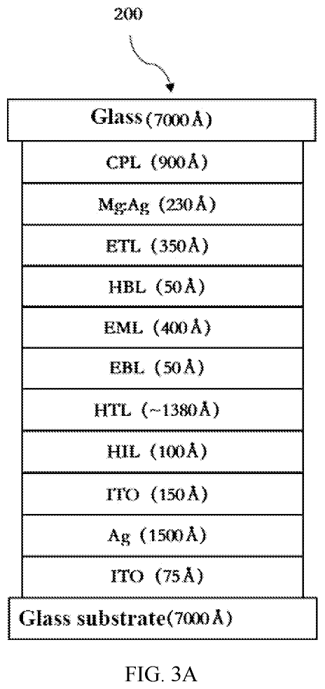

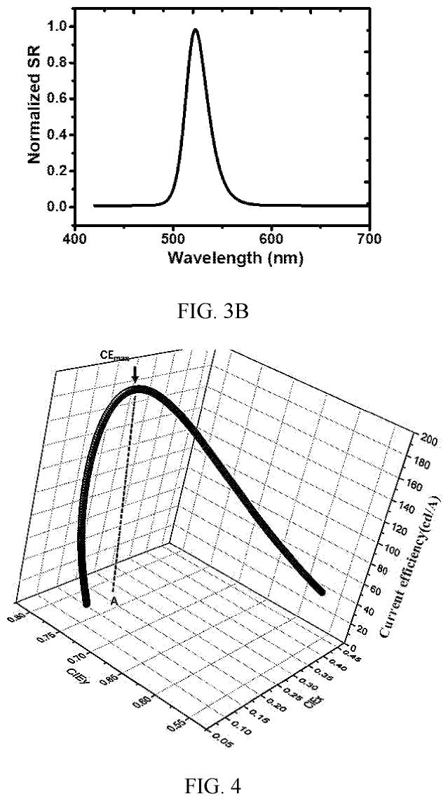

As used herein, the term “simulation” refers to the simulation of optical simulation software only by the refractive index curve and thickness of each layer of material only, excluding electrical simulation and the like. The simulation software used in the present disclosure is Setfos 5.0 semiconductor thin film optical simulation software developed by FLUXiM. The device structure adopted in the simulation is shown in FIG. 3A. Specifically, on a glass substrate having a thickness of 7000 Å, the first electrode (anode) adopts a three-layer structure of ITO (75 Å)/Ag (1500 Å)/ITO (150 Å). HIL (hole injection layer) is formed by the compound HATCN, with a thickness of 100 Å. HTL (hole transporting layer) is formed by the compound HT. Since the HTL is a micro-cavity regulation layer, the HTL adopts an optimized thickness of about 1380 Å. On the HTL, the EBL (electron blocking layer) is formed by the compound GH1 with a thickness of 50 Å. On the EBL, the EML, with a thickness of 400 Å, is formed by the compound GH1 and GH2, and the organic luminescent dopant material. (EML is a light-emitting layer, the weight ratio of compound GH1 to GH2 to organic luminescent dopant material is 48:48:4). On the EML, the HBL (hole blocking layer) is formed by the compound HB, with a thickness of 50 Å. On the HBL, ETL (electron transporting layer) is formed by the compound ET and Liq (weight ratio 40:60), with a thickness of 350 Å. On the ETL is the second electrode (cathode) formed by an alloy of Mg and Ag, with a thickness of 230 Å. A CPL (capping layer), with a thickness of 900 Å, is disposed on the cathode. Glass with a thickness of 7000 Å is adopted on the CPL as the encapsulation layer. The specific structure of the preceding compounds is shown below. Since Setfos 5.0 is optical simulation software and the thickness and refractive index of each layer of the device structure is only needed to be determined during the simulation (the refractive index used for each organic layer is the corresponding to the refractive index when the material thickness is 300 Å), the preceding layer materials are merely examples and are not intended to limit the scope of the present disclosure. The PL spectrum data of the organic luminescent dopant material used in the EML is input into the simulation software. In this manner, performance changes that the organic luminescent dopant material of different PL spectra can bring to the device can be simulated. In addition, the recombination position of the EML is set in the middle of the light-emitting layer in the software.

As used herein, the method for testing the refractive index of organic materials is as follows: In the Angstrom Engineering evaporation machine, a material having a thickness of 30 nm is evaporated on a silicon wafer, and a refractive index curve at a wavelength of 400 nm to 800 nm is obtained by an ellipsometer test of ELLITOP SCIENTIFIC CO., LTD.

As used herein, the test method for the PL spectrum of the organic luminescent dopant material is as follows: a fluorescence spectrophotometer of a model of Lengguang F98 produced by Shanghai Lengguang Technology Co. is adopted for measurement, the photoluminescence spectrum (PL) and FWHM data of the material to be tested are measured, specifically, a sample of the material to be tested is prepared into a solution with a concentration of 1×10⁻⁶ mol/L with HPLC-grade toluene, nitrogen is purged into the prepared solution for 5 minutes to remove oxygen, the solution is excited with light with a wavelength of 500 nm at room temperature (298 K) and its emission spectrum is measured, and then FWHM data is directly read from the spectrum.

Full-color displays are widely used in our work and life, such as a mobile phone display screens, computer display screens, and a shopping mall advertisement display screens. Full-color displays are mainly used for displaying information such as texts, graphics, animation, and videos, which are displayed and imaged through pixel units. Each pixel unit controls RGB sub-pixels to display full-color images of different colors. Each pixel unit is composed of one or more RGB sub-pixels. Color reproduction is one of the most important features for identifying the quality of a full-color display, except for flatness, brightness, visual angles, white balance effects, and the like. The color reproduction generally refers to the color that can be expressed by the RGB sub-pixels in the display screen. BT.2020 is currently a color gamut requirement with the highest degree of color reproduction. The higher the BT.2020 coverage of the full-color display is, the higher the color reproduction is.

The color coordinate required by BT.2020 for the three primary colors of red, blue and green are (0.708, 0.292), (0.131, 0.046), and (0.170, 0.797), respectively. The red-light device and the blue-light device in the commonly used display panels can basically meet the color gamut requirements. The color gamut is mainly limited by the performance of the green-light device. Therefore, BT.2020 coverage for commonly used display panels is only about 80%. It is generally believed in the art that if the coverage of BT.2020 is greater than or equal to 85%, the requirements of BT.2020 wide color gamut color coordinates are considered to be basically met. To achieve such BT.2020 coverage, the color coordinates of green-light devices need to be in the following range: 0.110≤CIEx≤0.230 and 0.750≤CIEy≤0.820.

In addition to meeting color requirements, efficiency and device color cast are also issues to be considered for commercial panels. In the three-dimensional diagram as shown in FIG. 4, when the color coordinates (corresponding to point A) corresponding to the maximum value CEₘₐₓ of the device current efficiency CE meets the preceding range requirement of the color coordinates, an excellent wide color gamut material may become possible. However, if the micro-cavity effect is increased by adjustment of the HTL thickness or other method to obtain a color coordinate point that is relatively close to (0.170, 0.797), the efficiency of the color coordinate point corresponding to (0.170, 0.797) is not CEₘₐₓ, which may lead to a serious color cast on the one hand, and on the other hand, may impose a very demanding requirement on a manufacturing process such as controlling the film thickness, thereby increasing the difficulty of mass production. Therefore, when the device current efficiency CE reaches a maximum value, the corresponding color coordinates satisfy the preceding range requirements: 0.110≤CIEx≤0.230 and 0.750≤CIEy≤0.820, is an important consideration standard for wide-color gamut devices. To obtain good device performance (such as high efficiency and long life), meet the BT.2020 color gamut, and minimize the impact on the display quality, the performance of the top-emitting device is studied. Through simulation, it is found that only organic luminescent dopant materials with specific PL spectrum can be used to achieve the preceding goals.

In conjunction with the device structure shown in FIG. 3A, the present disclosure adopts the Setfos 5.0 semiconductor thin film optical simulation software developed by FLUXiM for simulation. The spectrum for simulation is shown in FIG. 3B. For simplicity of processing, a similar spectrum without shoulder peaks is designed. On this basis, the wavelength and FWHM are adjusted to obtain a series of spectra for simulation.

Simulation is based on the top-emitting device structure shown in FIG. 3A. First, a series of spectra similar to that of FIG. 3B, including four different full width at half maximum (FWHM), that is, 46 nm, 28 nm, 22 nm, and 16 nm. The spectrum is further red-shifted and blue-shifted at each FWHM to obtain a series of spectra with the maximum emission wavelength λₘₐₓ between 523 nm and 533 nm. The series of spectra are then substituted into the top emission device structure (structure is shown in FIG. 3A) for simulation. A set of correlations between current efficiency (CE) and color coordinates (CIEx, CIEy) (as shown in FIG. 4) is obtained. From the correlations, the efficiency maximum value CEₘₐₓ and the color coordinates corresponding to the efficiency maximum value can be obtained. Table 1 describes the CEₘₐₓ and its corresponding color coordinates CIEx and CIEy under a series of spectra obtained by simulating different combinations of FWHM and λₘₐₓ. Also listed is the BT.2020 coverage calculated from the color coordinates.

TABLE 1
Simulation Results

| FWHM | λₘₐₓ | | | CEₘₐₓ | BT.2020 |
|---|---|---|---|---|---|
| [nm] | [nm] | CIEx | CIEy | [cd/A] | coverage |
| 16 | 523 | 0.116 | 0.813 | 267 | 96.0% |
| | 525 | 0.130 | 0.809 | 279 | 97.0% |
| | 527 | 0.146 | 0.804 | 291 | 98.1% |
| | 529 | 0.160 | 0.797 | 301 | 98.8% |
| | 531 | 0.175 | 0.789 | 311 | 98.6% |
| | 533 | 0.189 | 0.770 | 320 | 95.2% |
| 22 | 523 | 0.146 | 0.798 | 243 | 96.6% |
| | 525 | 0.155 | 0.795 | 252 | 98.0% |
| | 527 | 0.172 | 0.786 | 261 | 98.4% |
| | 529 | 0.187 | 0.778 | 269 | 96.4% |
| | 531 | 0.200 | 0.770 | 276 | 94.6% |
| | 533 | 0.215 | 0.760 | 283 | 91.7% |
| 28 | 523 | 0.166 | 0.784 | 216 | 97.9% |
| | 525 | 0.175 | 0.781 | 224 | 97.5% |
| | 527 | 0.188 | 0.774 | 231 | 95.8% |
| | 529 | 0.203 | 0.765 | 238 | 93.7% |
| | 531 | 0.216 | 0.757 | 244 | 93.6% |
| | 533 | 0.225 | 0.748 | 250 | 89.8% |
| 46 | 523 | 0.227 | 0.742 | 166 | 89.4% |
| | 525 | 0.236 | 0.737 | 170 | 87.8% |
| | 527 | 0.246 | 0.730 | 174 | 86.0% |
| | 529 | 0.257 | 0.722 | 178 | 84.0% |
| | 531 | 0.267 | 0.715 | 181 | 82.3% |
| | 533 | 0.278 | 0.706 | 184 | 80.3% |

As can be seen from Table 1 that when the PL spectrum of the organic luminescent dopant material FWHM=16 nm, λₘₐₓ=523 nm, and the corresponding color coordinates are (0.116, 0.813), the maximum current efficiency CEₘₐₓ is obtained. The coverage of BT.2020 is 96.0%, meeting the requirements of BT.2020 wide color gamut green-light OLED material color coordinates. Under the condition, the color coordinates are close to the color coordinates of BT.2020 green light (0.170, 0.797), which features an excellent BT.2020 green-light material. Similarly, when λₘₐₓ=525 nm, 527 nm, 529 nm, 531 nm, or 533 nm, the BT.2020 coverage of the color coordinates corresponding to the maximum current efficiency CEₘₐₓ is greater than 95%, which features an excellent BT.2020 green-light material.

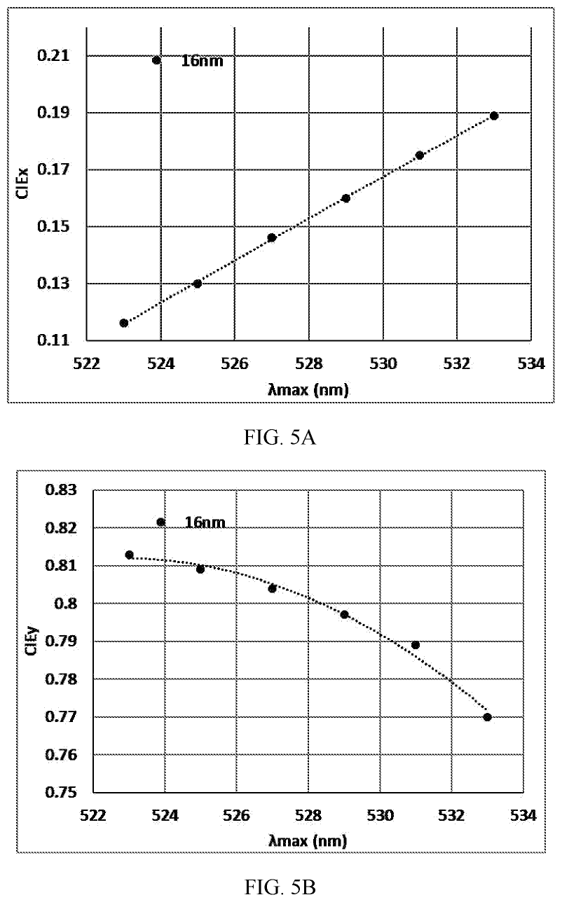

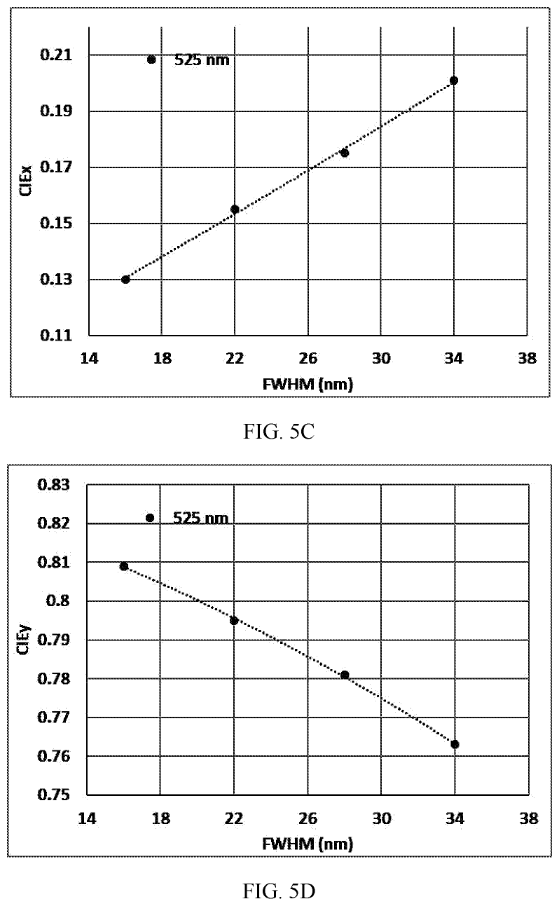

It is worth noting that under the condition of fixed FWHM, within a small range, λₘₐₓ and CIEx, λₘₐₓ and CIEy basically form a quadratic relationship. As shown in FIGS. 5A and 5B, formulas obtained by fitting are CIEx=−1.7857×10⁻⁵×(λₘₐₓ)²+0.02620×(λₘₐₓ)−8.70244 and CIEy=—3.8839×10⁻⁴×(λₘₐₓ)²+0.40611×(λₘₐₓ)−105.34910, respectively. Therefore, it can be seen from the data corresponding to different λₘₐₓ described in the table that in the range that 523 nm≤λₘₐₓ≤533 nm, the color coordinate range of the device satisfies: 0.110≤CIEx≤0.230 and 0.750≤CIEy≤0.820.

Similarly, when FWHM of the PL spectrum of the organic luminescent dopant material equals 22 nm, in the range that 523 nm≤λₘₐₓ≤533 nm, the color coordinates satisfy: 0.110≤CIEx≤0.230 and 0.750≤CIEy≤0.820, and BT.2020 coverage is greater than 90%. When FWHM of the PL spectrum of the organic luminescent dopant material equals 28 nm, in the range that 523 nm≤λₘₐₓ≤533 nm, the color coordinates satisfy: 0.110≤CIEx≤0.230 and 0.750≤CIEy≤0.820, and BT. 2020 coverage is greater than 90%. It is worth noting that under the condition of fixed λₘₐₓ, within a small range, CIEx and FWHM, CIEy and FWHM basically form a quadratic relationship. As shown in FIGS. 5C and 5D, formulas obtained by fitting are CIEx=6.9444×10⁻⁶×(FWHM)²+0.00354×FWHM+0.07219 and CIEy=−2.7778×10⁻⁵×(FWHM)²−0.00114×FWHM+0.83422, respectively. Therefore, it can be seen from the data under different FWHM conditions described in the table that in the range that 16 nm≤FWHM≤32 nm, the color coordinates of the device can all satisfy: 0.110≤CIEx≤0.230 and 0.750≤CIEy≤0.820.

Conversely, when FWHM of the PL spectrum of the organic luminescent dopant material is too large, the device cannot achieve a high BT.2020 coverage.

For example, when FWHM of the PL spectrum of the organic luminescent dopant material equals 46 nm, and the current efficiency reaches the maximum value CEₘₐₓ under the condition that λₘₐₓ=523 nm, the corresponding color coordinates are (0.227, 0.742), far from the BT.2020 green-light color coordinate requirement (0.170, 0.797), which does not feature an excellent BT.2020 wide color gamut green OLED material. Moreover, the device cannot achieve high coverage of the BT.2020 color gamut. In the range that 525 nm≤λₘₐₓ≤533 nm, when the current efficiency reaches the maximum CEₘₐₓ, the color coordinate range is: CIEx≥0.236 and CIEy≤0.742, and the BT.2020 coverage is less than 90%.

According to the preceding simulation results, an organic luminescent dopant material Compound GD whose PL spectrum has a FWHM of 32 nm and where λₘₐₓ=523 nm is selected to prepare a green phosphorescent top-emitting organic electroluminescent device 100 (the device structure is shown in FIG. 1). The device data is tested to further verify the simulation results. The details are as follows.

Firstly, a 0.7 mm thick glass substrate is used, on which indium tin oxide (ITO) 75 Å/Ag 1500 Å/ITO 150 Å are pre-patterned as an anode 110. The substrate is dried in a glove box to remove moisture, mounted on a substrate holder, and transferred into a vacuum chamber. The organic layers specified below are sequentially evaporated on the anode layer by vacuum thermal evaporation at a rate of 0.01-10 Å/s in a vacuum of about 10⁻⁶ Torr. First, the compound HATCN is simultaneously evaporated as the hole injection layer (HIL, 100 Å) 120. The compound HT is evaporated as the hole transporting layer (HTL, 1380 Å) 130. At the same time, the HTL is used as the micro-cavity regulation layer. Next, compound GH1 is evaporated as an electron blocking layer (EBL, 50 Å) 140, on which compounds GH1, GH2, and GD are simultaneously evaporated as an emissive layer (EML, the weight ratio of compounds GH1 to GH2 to GD is 48:48:4, 400 Å) 150. Compound HB is evaporated as a hole blocking layer (HBL, 50 Å) 160. Compound ET and Liq are co-deposited as an electron transporting layer (ETL, the weight ratio of compound ET and Liq is 40:60, 350 Å) 170. Afterwards, metal ytterbium (Yb) with a thickness of 10 Å is evaporated as the electron injection layer (EIL) 180. Metal magnesium (Mg) and metal silver (Ag) are evaporated simultaneously as the cathode (Cathode, 10:90, 140 Å) 181. Next, compound CPL1 is evaporated as a capping layer (CPL, 800 Å) 182. Compound CPL1 is a material with a refractive index of about 2.01 at 530 nm. The device is transferred back to the glove box and encapsulated with a glass lid 190 to complete the device.

The structures of the compounds used are as follows:

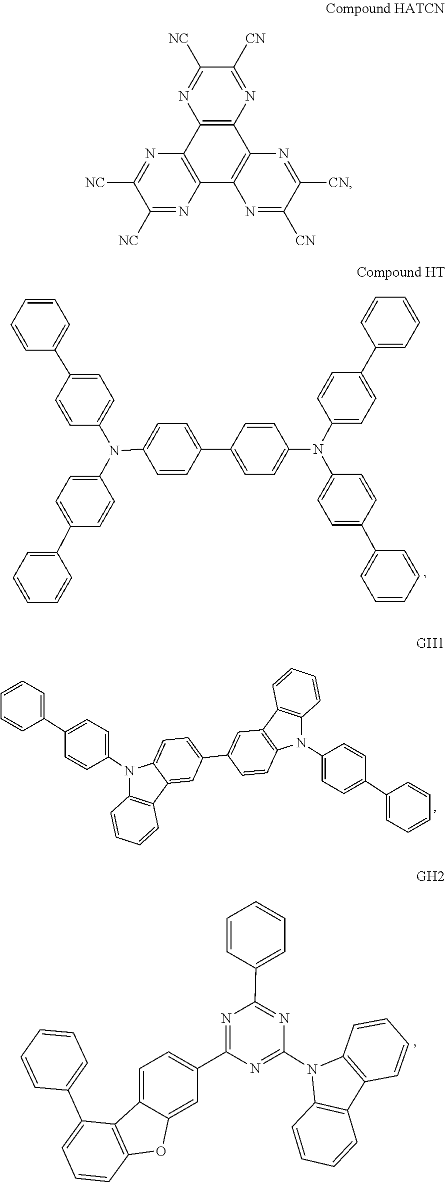 [SMILES: N#Cc1nc2c3nc(C#N)c(C#N)nc3c3nc(C#N)c(C#N)nc3c2nc1C#N ; c1ccc(-c2ccc(N(c3ccc(-c4ccccc4)cc3)c3ccc(-c4ccc(N(c5ccc(-c6ccccc6)cc5)c5ccc(-c6ccccc6)cc5)cc4)cc3)cc2)cc1 ; c1ccc(-c2ccc(-n3c4ccccc4c4cc(-c5ccc6c(c5)c5ccccc5n6-c5ccc(-c6ccccc6)cc5)ccc43)cc2)cc1 ; c1ccc(-c2nc(-c3ccc4c(c3)oc3cccc(-c5ccccc5)c34)nc(-n3c4ccccc4c4ccccc43)n2)cc1]

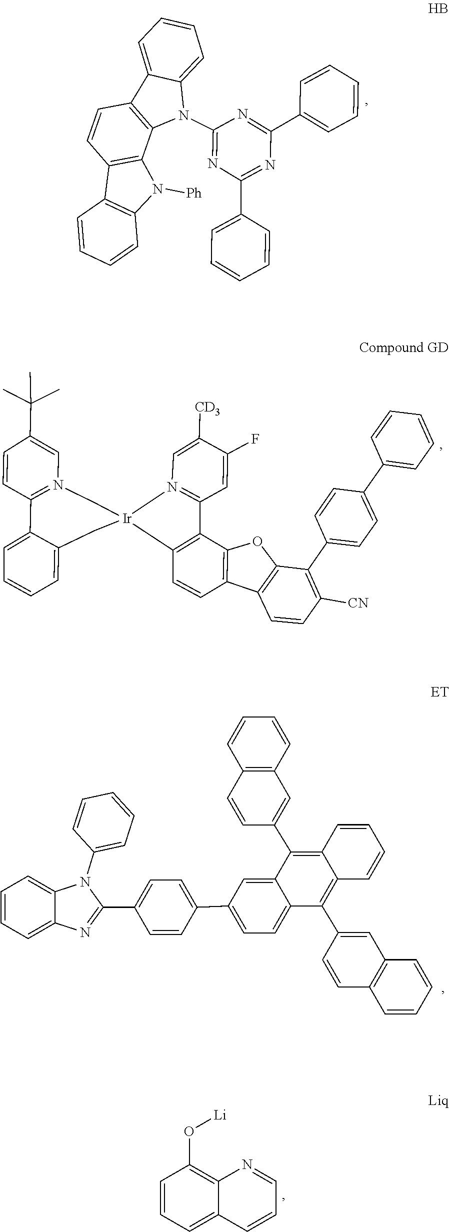

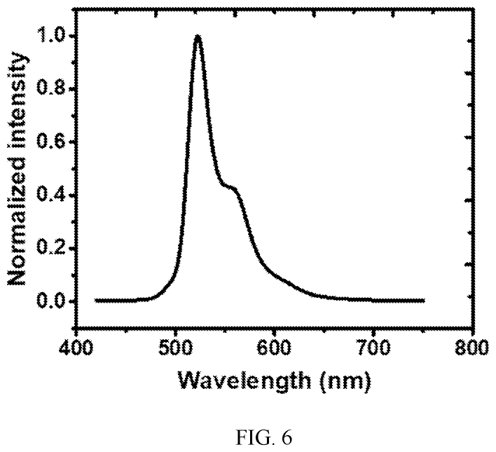

The PL spectrum of GD is shown in FIG. 6. The FWHM is 32 nm and the maximum emission wavelength λₘₐₓ=523 nm. The color coordinates of the device, when current efficiency reaches the maximum, that is, CEₘₐₓ=175 cd/A, are (0.189, 0.767). The color coordinates closest to (0.170, 0.797) in the emission spectrum of the device are (0.169, 0.777), and the corresponding current efficiency is 171 cd/A. The BT.2020 coverage of the device is as high as 97.3%, reaching an excellent BT.2020 coverage level. In addition, under the condition of initial brightness of 110000 cd/m² (the current density of the device under this condition is 80 mA/cm²), the device lifetime LT95 is 42 h, which is an excellent device lifetime. The preceding proves that the organic electroluminescent device of the present disclosure has excellent performance and broad commercial application prospects.

Due to the excellent performance of the organic electroluminescent device of the present disclosure, a full-color display including the organic electroluminescent device of the present disclosure can achieve extremely high BT.2020 color gamut coverage with excellent color reproduction.

It is to be understood that various embodiments described herein are merely illustrative and not intended to limit the scope of the present disclosure. Therefore, it is apparent to the persons skilled in the art that the present disclosure as claimed may include variations of specific embodiments and preferred embodiments described herein. Many of the materials and structures described herein may be replaced with other materials and structures without departing from the spirit of the present disclosure. It is to be understood that various theories as to why the present disclosure works are not intended to be limiting.

What is claimed is:

1. An organic electroluminescent device, at least comprising:
a substrate;
a first electrode disposed on the substrate;
a second electrode disposed over the first electrode; and
an organic layer disposed between the first electrode and the second electrode,
wherein the first electrode has high reflectivity, the second electrode is translucent or transparent, and
the organic layer further comprises an organic luminescent dopant material whose PL spectrum satisfies: FWHM≤32 nm and 523 nm≤λₘₐₓ≤533 nm;
wherein color coordinates (CIEx, CIEy) of the organic electroluminescent device when maximum current efficiency CEₘₐₓ is reached satisfy following conditions:
0.110≤CIEx≤0.230;
0.750≤CIEy≤0.820.

2. The organic electroluminescent device according to claim 1, wherein the color coordinates satisfy: 0.150≤CIEx≤0.200; and preferably, the color coordinates satisfy: 0.165≤CIEx≤0.175.

3. The organic electroluminescent device according to claim 1, wherein the color coordinates satisfy: 0.750≤CIEy≤0.813; and preferably, the color coordinates satisfy: 0.770≤CIEy≤0.800.

4. The organic electroluminescent device according to claim 1, wherein the PL spectrum of the organic luminescent dopant material satisfies following conditions: 28 nm<FWHM≤32 nm, and 523 nm≤λₘₐₓ≤527 nm.

5. The organic electroluminescent device according to claim 1, wherein the PL spectrum of the organic luminescent dopant material satisfies following conditions: 22 nm<FWHM≤28 nm, and 523 nm≤λₘₐₓ≤527 nm.

6. The organic electroluminescent device according to claim 1, wherein the PL spectrum of the organic luminescent dopant material satisfies following conditions: 16 nm<FWHM≤22 nm, and 525 nm≤λₘₐₓ≤529 nm.

7. The organic electroluminescent device according to claim 1, wherein the PL spectrum of the organic luminescent dopant material satisfies following conditions: FWHM≤16 nm, and 529 nm≤λₘₐₓ≤533 nm.

8. The organic electroluminescent device according to claim 1, wherein the CEₘₐₓ≥160 cd/A.

9. The organic electroluminescent device according to claim 1, wherein the first electrode is an anode, and the second electrode is a cathode.

10. The organic electroluminescent device according to claim 1, wherein average reflectivity of the first electrode in a visible region is greater than 50%; preferably, the average reflectivity of the first electrode in the visible region is greater than 70%; and more preferably, the average reflectivity of the first electrode in the visible region is greater than 80%.

11. The organic electroluminescent device according to claim 1, wherein average transmittance of the second electrode in a visible region is greater than 15%; preferably, the average transmittance of the second electrode in the visible region is greater than 20%; and more preferably, the average transmittance of the second electrode in the visible region is greater than 25%.

12. The organic electroluminescent device according to claim 1, wherein the first electrode comprises a material selected from a group consisting of Ag, Al, Ti, Cr, Pt, Ni, TiN, and from a combination of preceding materials with ITO and/or MoOx (molybdenum oxide); and
the second electrode comprises a material selected from a group consisting of MgAg alloy, MoOx, Yb, Ca, ITO, IZO, and from a combination of preceding materials.

13. A full-color display, comprising the organic electroluminescent device of claim 1.

14. The full-color display according to claim 13, wherein color coordinates of red light comprise (0.708, 0.292), and color coordinates of blue light comprise (0.131, 0.046).

15. The full-color display according to claim 13, wherein BT.2020 coverage of the full-color display is greater than or equal to 85%; preferably, the BT.2020 coverage of the full-color display is greater than or equal to 90%; and more preferably, the BT.2020 coverage of the full-color display is greater than or equal to 95%.
